(19) United States
(12) Patent Application Publication
(10) Pub. No.: US 2012/0092019 A1
(43) Pub. Date: Apr. 19, 2012

(54) Electric Field Signature Detection Using Exciter-Sensor Arrays

(75) Inventor: Dieter Wolfgang Blum, Aldergrove (CA)

(73) Assignee: RAMPART DETECTION SYSTEMS LTD., Murrayville (CA)

(21) Appl. No.: 13/100,732

(22) Filed: May 4, 2011

Related U.S. Application Data
(60) Provisional application No. 61/331,596, filed on May 5, 2010.

(51) Int. Cl. G01R 29/12

(52) U.S. Cl. 324/457

(57) ABSTRACT

An electric field signature detector for detecting and identifying objects that uses multiple electrostatic sensor nodes each having a passive sensing electrode whose free conduction electrons are displacement responsive to an externally applied or sensed electric field potential, and a transimpedance converter and amplifier exhibiting ultra-high input impedance for translating low level input displacement current from a sensing electrode into a useable output signal in response to a charge displacement signal induced on the passive sensing electrode by an external electric field. The electric field signature detector further includes an exciter for providing a reference electric field used in the retrieval and processing of an electric field signature representative of an object and class of object under investigation. The electric field signature detector having uses including military, security, anti-terrorist, and defense related.

This application claims priority to U.S. patent application Ser. No. 61/331,596 filed May 5, 2010 entitled “Electric Field Signature Detection Using Exciter-Sensor Arrays” by Dieter Wolfgang Blum of Aldergrove, British Columbia, CANADA.

### BACKGROUND OF THE INVENTION

1. Field of the Invention

This invention relates generally to the detection of objects, and more particularly to an apparatus for the detection and identification of objects using electric field signature detection with exciter-sensor arrays.

2. Description of Related Art

Distortions in the electric field surrounding an object are typically caused by either emission of an electric field through the imbalance of charges, for example, the electric field surrounding a power line, electric motor, transformer, some plastics, and the like, or by the disruption of the isopotential lines of the earth's electric field when an object passes or is placed within the earth's natural potential gradient. Humans will distort this gradient as they move, and such distortions can be detected with the appropriate electronics.

The detection of a rocket exhaust, a jet engine, a weapons discharge, a ballistic projectile in flight, a helicopter rotor in use, a land mine, or an explosive or contraband device contained on a person, are all of strategic and defensive military importance, and are vital to national security in an age of terrorism and unrest.

Detection devices using infra red detectors, visual detectors, audible detectors, and magnetic detectors are known in the art. For example, a common way to detect metal objects is by way of a metal detector that passes an alternating current through a coil to produce an alternating magnetic field. When the coil is passed by a metal object, eddy currents set up in the metal object and create an alternating magnetic field that can be detected by another coil, essentially acting as a magnetometer. Metal detectors have proven valuable in the detection of land mines, weapons, prospecting, the detection of foreign bodies in food, and the detection of steel reinforcements in concrete.

Another example of detection is that of visual detection. In WO 93,09523 entitled Video-Based Object Acquisition, Identification, And Velocimetry, to Blum, an apparatus is described that determines the time in which an object traverses a distance using a sophisticated visual scanning technique.

Other devices used to detect objects include ones that rely on radar. Ground penetrating radar, for example, will provide an indication of what is below the surface of the earth.

A much lesser studied way to detect objects is through the detection of the electric field distortion around or generated by the object to be detected. There have been several attempts to use electrostatic fields for the detection of objects using gradiometers made from metal foil, field mills, or simple Field Effect Transistor Bias circuits. None of these attempts have been able to discern and further process the small but vitally important electric field changes that are the unique signatures of objects to be detected.

Electrostatic fields have been studied since the 17^{th} and 18^{th} centuries. The interaction between electrically charged particles was studied by Charles Augustin de Coulomb, who in 1783 described this relationship as the magnitude of the electrostatic force between two point electric charges being directly proportional to the product of the magnitude of each of the charges and inversely proportional to the square of the distance between the two charges. This relationship came to be known as Coulombs law, and has been the basis for electrostatic detection. The interaction with and influence on electrostatic fields by charged insulating (dielectric) and charged conductive bodies or objects is well known and understood and has been modeled and investigated extensively. The interaction with and influence on electrostatic fields by noncharged/uncharged (neutral) insulating and conductive bodies or objects has not been investigated as thoroughly as the above, and is less well understood.

The detection of charged objects such as aircraft, has been described in U.S. Pat. No. 4,931,740 to Hassanzadeh et al, entitled Electrostatic Field Gradient Sensor. The sensors of Hassanzadeh employ at least two probes displaced from each other which have attached beads of radioactive material to provide free ions in the vicinity of the probe and incorporate the use of a differential electrostatic voltmeter. Further, an aircraft will generate a significant charge buildup in flight.

The sensing of non-charged/uncharged objects moving relative to an electrostatic field that is quasi-stationary requires the detection not of ionic currents due to corona discharges, but the detection of actual electrostatic field potential changes, distortions and gradients. For the detection of uncharged objects vertically located less than 100 meters above the earth's ground surface, objects are deemed to be immersed in the earth's ambient electric field (vertical) of ˜120V/m and this can change slowly or even rapidly with respect to magnitude and polarity (lightning, thunderclouds etc.)

The superimposition of a reference electrostatic field onto the ambient is easily done and methods for generating high voltages below the corona limit (dielectric breakdown of air) are well known and include triboelectric (frictional), inductive (electrostatic) and electronic means.

The sensing of the weak alterations in the electrostatic field is extremely difficult, as ideally one is sensing charge displacement (due to potential gradients), not direct potential (as there is no contact, nor continuous current flow, as in ionic discharge currents). This has been done in the past utilizing high-impedance electrometers. However, these require a reference to earth ground (or a virtual ground) and further, suffer from distributed capacitance effects and similar anomalies.

What is required, therefore, is a technique that minimizes the effects of distributed capacitance, the dependence on the earth's electrostatic field, and utilizes electrostatic field potentials that are non-corona and safe.

Electrostatic field sensors have in the past employed Field Effect Transistors such as Insulated Gate Field Effect Transistors that are wired in series with a DC source where the gate is tied to a short antenna. A LED or similar indicator is wired in series between the DC source and the drain or source of the FET.

The present invention, however, uses a class of ultra-low bias-current FET front end op amps (transimpedance converter/amplifier) (current [charge displacement] to voltage converter). For vector applications (roadside bomb detection) and for portal and other imaging applications, inverse electrostatic field modeling may be used, thereby creating a sensed/virtual image from the gathered data (minimal in the case of IED's, maximal in the case of the imaging portal.)

It is therefore an object of the present invention to provide an electrostatic detection apparatus. It is another object of the present invention to provide an electrostatic gradiometer using exciter-sensor arrays. It is yet another object of the present invention to provide an electrostatic detection apparatus that gathers and processes electrostatic signatures of objects. It is further an object of the present invention to provide a method of detecting objects using electrostatic field vectoring.

### BRIEF SUMMARY OF THE INVENTION

In accordance with the present invention, there is provided an electric field signature detector for detecting and identifying objects comprising a high voltage exciter electrically coupled to an antenna for providing an electrostatic field; a sensor for detecting an electrostatic signature resulting from interaction of an object being detected with an electrostatic field being generated by the high voltage exciter; the sensor comprising an amplifier, an antenna electrically coupled to an input of the amplifier, and an output of the amplifier electrically coupled to an analog to digital converter and processor.

The foregoing paragraph has been provided by way of introduction, and is not intended to limit the scope of the invention as described by this specification and the attached drawings.

### BRIEF DESCRIPTION OF THE DRAWINGS

The invention will be described by reference to the following drawings, in which like numerals refer to like elements, and in which:

FIG. 1 illustrates an array of electrostatic exciters and electrostatic sensors, wherein for every sensor there are a multitude of exciters.

FIG. 2 illustrates an array of electrostatic exciters and electrostatic sensors, wherein for every exciter there are a multitude of sensors.

FIG. 3 illustrates an array of electrostatic exciters and electrostatic sensors, wherein there are an equal number of exciters and sensors.

FIG. 4 shows an example of one embodiment of the present invention in use with representative field contour lines.

FIG. 5 is a top view of a personnel area to be electrostatically imaged, showing exciter points on the left side and sensor points on the right side.

FIG. 6 is a schematic representation of the operating, control and processing system of the present invention.

FIG. 7 is an example computer/video image of a public area being imaged, with detected humans in silhouette and suspected targets of interest.

FIG. 8 shows a side view of one embodiment of the present invention in a mobile application with various distributed coupling capacitances depicted.

FIG. 9 illustrates one embodiment of the present invention in a mobile application wherein there is shown the use of two sensors for vectoring capability and the use of a single exciter.

FIG. 10 is a sample image from a mobile vehicle windshield with a computer/video display illuminating/indicating suspect targets.

FIG. 11 shows a frontal view of one embodiment of the present invention in a static screening portal application.

FIG. 12 is a side view of FIG. 11.

FIG. 13 shows a frontal view of one embodiment of the present invention in a pass through screening portal application.

FIG. 14 is a side view of FIG. 13.

FIG. 15 is a frontal view of the static screening portals of FIG. 11 or 13 showing a human carrying a PBIED.

FIG. 16 shows a typical computer/video screen of the present invention.

FIG. 17 is a schematic block diagram of an electrostatic exciter of the present invention.

FIG. 18 is a schematic block diagram of a sensor of the present invention.

FIG. 19 shows a soldier-borne boom based electric field signature detector.

FIG. 20 shows a plan view of the soldier-borne boom based electric field signature detector.

FIG. 21 shows a plan view of the soldier-borne boom based electric field signature detector with the boom in an extended position.

The present invention will be described in connection with a preferred embodiment, however, it will be understood that there is no intent to limit the invention to the embodiment described. On the contrary, the intent is to cover all alternatives, modifications, and equivalents as may be included within the spirit and scope of the invention as defined by this specification, attached drawings and claims.

### DESCRIPTION OF THE PREFERRED EMBODIMENTS

For a general understanding of the present invention, reference is made to the drawings. In the drawings, like reference numerals have been used throughout to designate identical elements.

The present invention will be described by way of example, and not limitation. Modifications, improvements and additions to the invention described herein may be determined after reading this specification and viewing the accompanying drawings; such modifications, improvements, and additions being considered included in the spirit and broad scope of the present invention and its various embodiments described or envisioned herein.

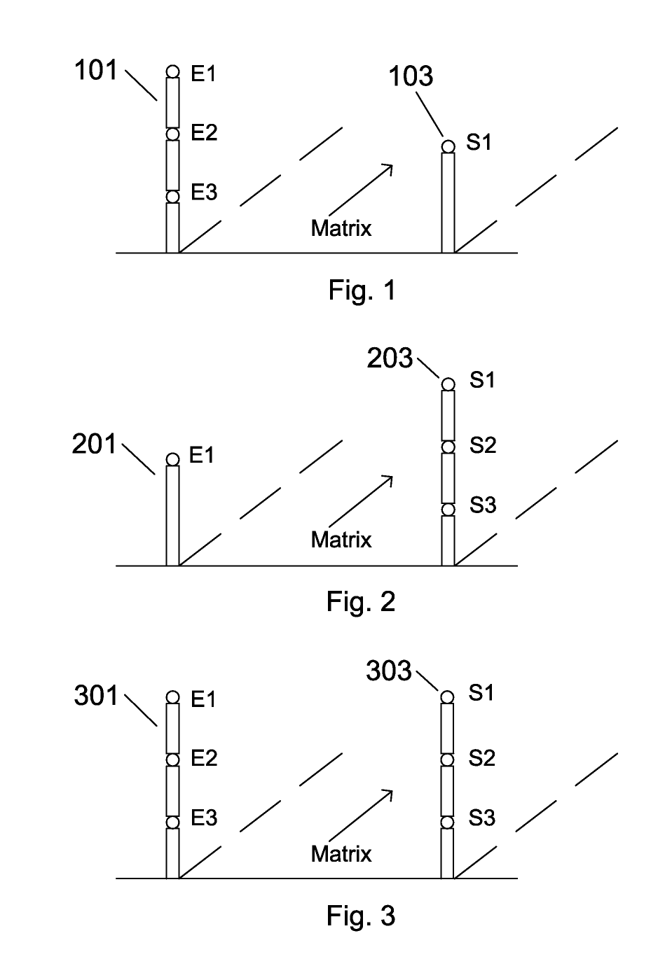

FIGS. 1, 2, and 3 depict various topologies of the sensor and exciter array.

Referring first to FIG. 1, there is illustrated an array of vertical electrostatic excitation nodes E1, E2 and E3, shown as 101, and electrostatic sensing node S1 depicted as 103. In the example of FIG. 1, for every sensor there are a multitude of exciters.

By way of example and not limitation, said electrostatic excitation nodes are seen to be vertically arranged and spaced approximately 1 meter apart for a total height of about 3 meters above the ground surface. In the example, said electrostatic sensing node is seen to be vertically disposed approximately 1.5 meters above the ground surface. Said electrostatic excitation nodes and said electrostatic sensing nodes are horizontally spaced apart by a distance of as much as 150 meters. The array depicted is illustrated to be extending rearward some distance, by as much as 100 meters or more. In this manner, and again by example, the array can be seen to provide coverage to an area of about 150 meters×100 meters.

Now with reference to FIG. 2, there is illustrated an array of vertical electrostatic sensing nodes S1, S2 and S3 depicted as 203 and electrostatic excitation node E1 depicted as 201. In this example, there is one excitation node and multiple sensing nodes. By way of example and not limitation, said electrostatic sensing nodes are seen to be vertically arranged and spaced approximately 1 meter apart for a total height of about 3 meters above the ground surface. Said electrostatic excitation node is seen to be vertically disposed approximately 1.5 meters above the ground surface. Said electrostatic sensing nodes and said electrostatic excitation node are horizontally spaced apart by a distance of as much as 150 meters. Said array is seen to be extending rearward some distance, by as much as 100 meters or more. In this manner, and again by way of example, the array can be seen to provide coverage to an area of about 150 meters×100 meters.

With reference to FIG. 3, there is illustrated an array of vertical electrostatic sensing nodes S1, S2 and S3 labeled as 303, and electrostatic excitation nodes E1, E2 and E3 labeled as 301. In this example, there are an equal number of exciters and sensors. Said electrostatic sensing nodes are seen to be vertically arranged and spaced approximately 1 meter apart for a total height of about 3 meters above the ground surface. Again by way of example and not limitation, said electrostatic excitation nodes are seen to be vertically arranged and spaced approximately 1 meter apart for a total height of about 3 meters above the ground surface. Said electrostatic sensing nodes and said electrostatic excitation nodes are horizontally spaced apart by a distance of as much as 150 meters. Said array is seen to be extending rearward some distance, by as much as 100 meters or more. In this manner, the array can be seen to provide coverage to an area of about 150 meters×100 meters.

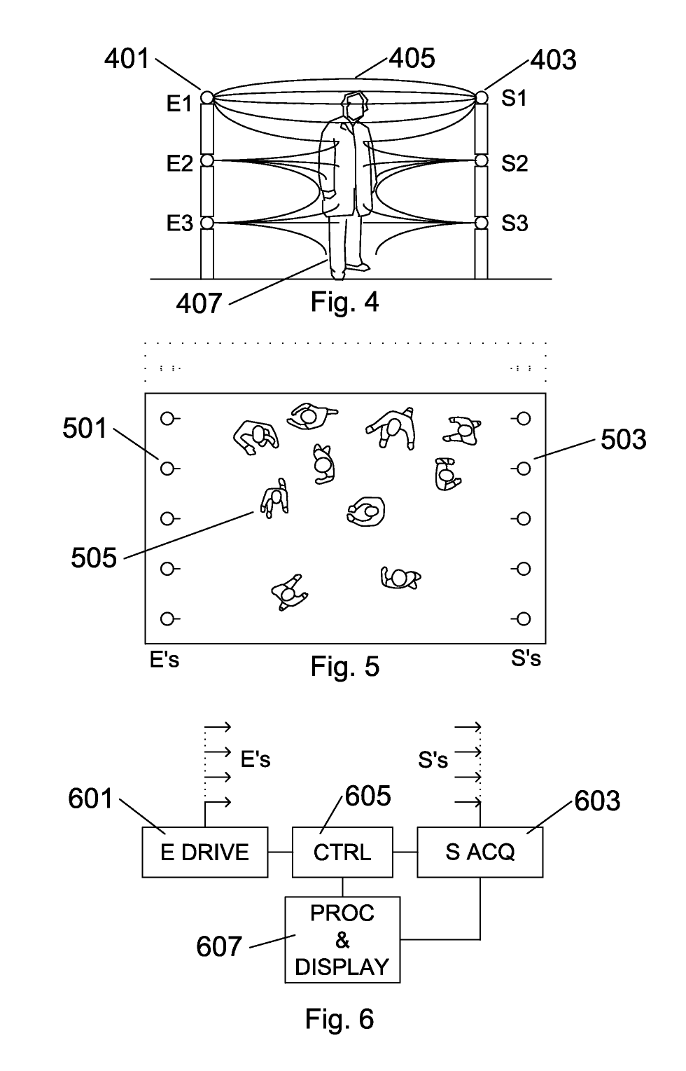

Now with reference to FIG. 4, there is illustratively shown a front view of the present invention as applied towards detection of human borne contraband, such as person borne improvised explosive devices. In this illustration there is shown only a single set of electrostatic excitation nodes E1, E2 and E3 (401). Said electrostatic excitation nodes are arranged vertically as explained previously by way of FIG. 3. Further, in this illustration, there is shown only a single set of electrostatic sensing nodes S1, S2 and S3 (403). Said electrostatic sensing nodes are again arranged vertically as explained previously by way of FIG. 3. For illustrative purposes only, there are shown various electrostatic field lines (contours) emanating from said electrostatic excitation nodes and crossing the intervening space between the horizontally spaced apart excitation and sensing points, some of said field lines not encountering any dielectric material interaction or distortion, and some encountering dielectric material or materials, here shown to be a human body, and illustrating interaction and distortion of said electrostatic field lines (contours) as a result thereof. Such electric field line distortion is used by the present invention to provide detection means and also may, in some embodiments of the present invention, be used as an electrostatic signature for identification of objects. In addition, in some embodiments of the present invention, such electrostatic signatures are electronically stored in a database or similar electronic repository, and may be used to improve the accuracy of the identification techniques of the present invention and the various embddiments described and envisioned herein.

Now shown in FIG. 5 there is shown in top view, an area 505 to be electrostatically imaged or monitored. FIG. 5 depicts electrostatic excitation node points 501 on the left-hand side and electrostatic sensing node points 503 on the right-hand side (further as shown previously in FIG. 4.) Also shown are people within said area 505 to be electrostatically imaged or monitored.

With reference now to FIG. 6, there is illustrated schematically the operating, control and processing system of the present invention. Illustrated are a multiplicity of electrostatic excitation nodes (E's), their electrostatic drive system (E DRIVE) 601, controller (CTRL) 605, a multiplicity of electrostatic sensing nodes (S's), electrostatic sensing acquisition system (S ACQ) 603, processing and display system 607 and various interconnections there between. The processing and display system 607 may, in one embodiment, be a computer. The processing and display system 607 may be coupled to the controller 605 by way of a wired connection, an optical connection, or a wireless connection.

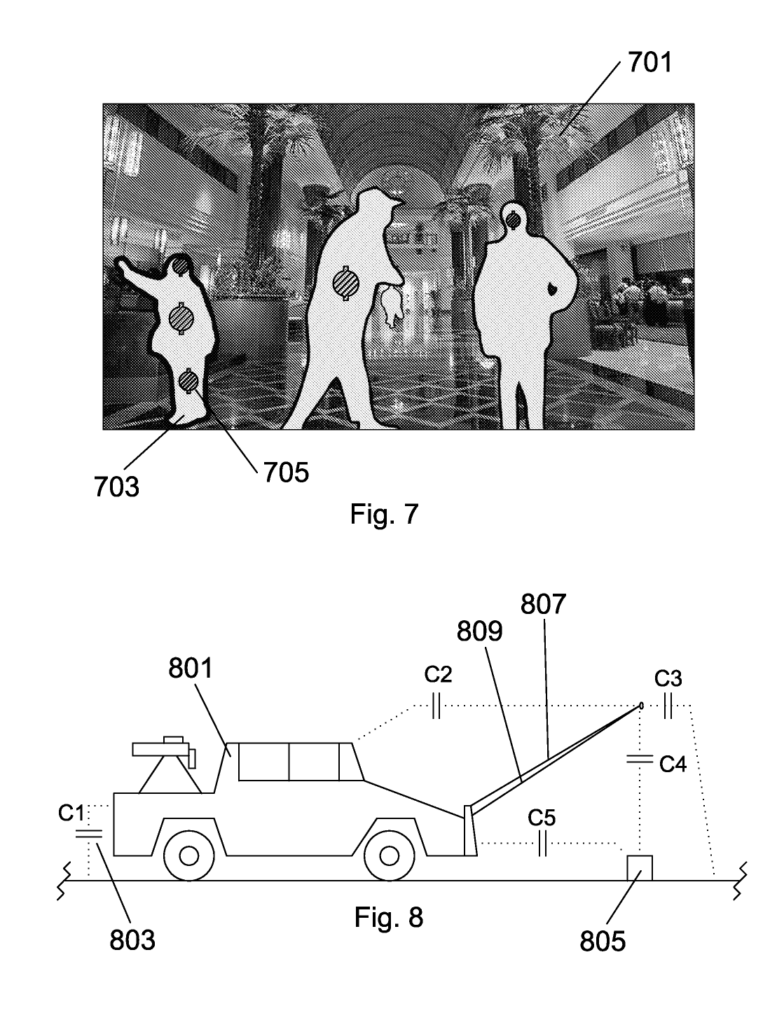

FIG. 7 depicts a video image of a public area 701 being imaged or monitored, with detected humans bodies 703 outlined/silhouetted, along with suspected dielectric target anomalies of interest 705 overlaid graphically thereon (these could be, for example, person borne improvised explosive devices, or external or internal prostheses.)

Now shown in FIG. 8 is a side view of a further application of the present invention, in this case a mobile system oriented towards detection of buried or hidden roadside/roadway improvised explosive devices (IEDs.) Shown is the vehicle metallic body 801, insulating/dielectric tires, and an example of electrostatic exciter 807 or electrostatic sensor 809 dielectric boom/mast. Also shown is a roadside target object 805. Said vehicle metallic body 801 is seen to be resting upon the ground via its tires and can be deemed for the most part to be insulated therefrom. Also shown in FIG. 8 are various distributed electrostatic coupling capacitances 803, for example, C1 between said vehicle body and ground; C2 between said vehicle body and said electrostatic exciter or electrostatic sensor located at the end of said dielectric boom/mast; C3 between said ground and said electrostatic exciter or electrostatic sensor located at the end of said dielectric boom/mast; C4 between said roadside target object and said electrostatic exciter or electrostatic sensor located at the end of said dielectric boom/mast; and, C5 between said roadside target object and said vehicle body.

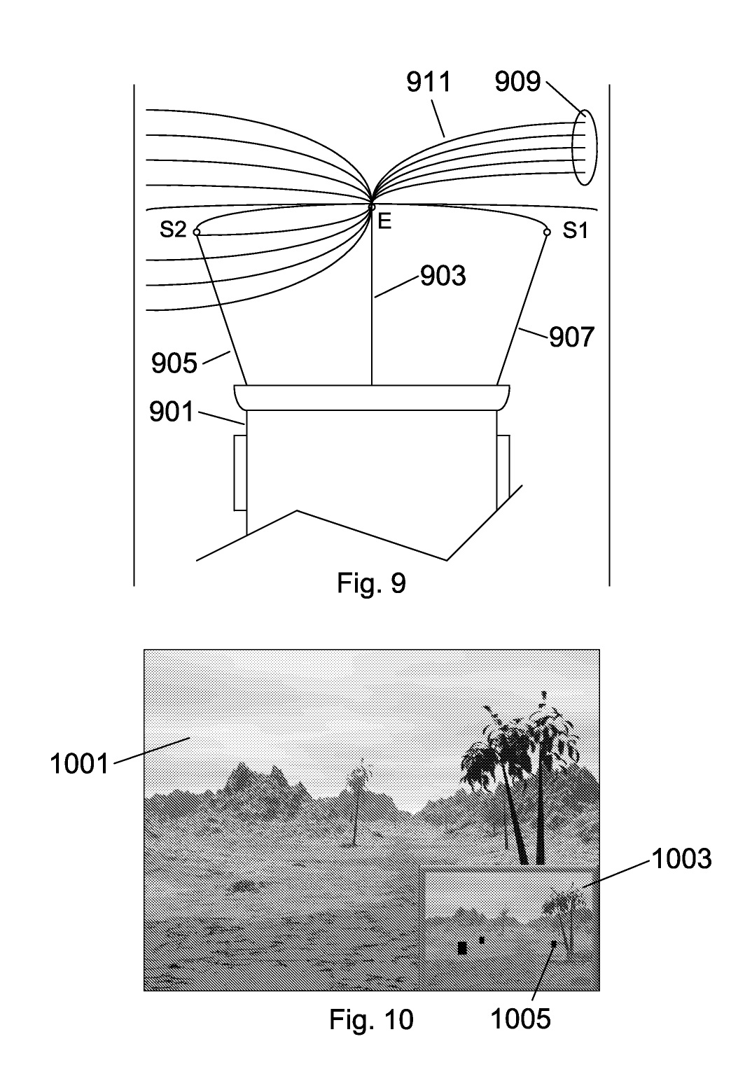

Now further illustrated in FIG. 9 is a mobile application as previously described by way of FIG. 8 wherein there is shown the use of two sensors for vectoring capability and the use of a single exciter. There is shown in FIG. 9 a roadbed; said metallic vehicle body 901, said insulating/dielectric tires; three dielectric booms/mast's; wherein at the end of the middle boom/mast 903 is located an electrostatic exciter E; and wherein at the ends of the two outside booms/masts 905 and 907 are located electrostatic sensors S2 and S1. Also shown is said roadside target 909, and example electrostatic field lines/contours 911, representative of alterations or distortions to the sensed electrostatic field produced by said electrostatic exciter. As shown here the use of a single electrostatic exciter, along with said two electrostatic sensors, will provide for vectoring capability to potential roadside targets.

Now illustrated in FIG. 10 is an example image 1001 through a mobile vehicle windshield, along with a computer/video display 1003 illuminating/indicating suspect roadside targets thereon (for example, 1005). These suspect roadside targets could be roadside improvised explosive devices or the like. A GIS driven database keeps track of previous sensed and investigated roadside targets (that is, those detected and investigated during a previous drive-by) and compares currently sensed targets thereto, and therefore alerts to the targets or changes to previous ones.

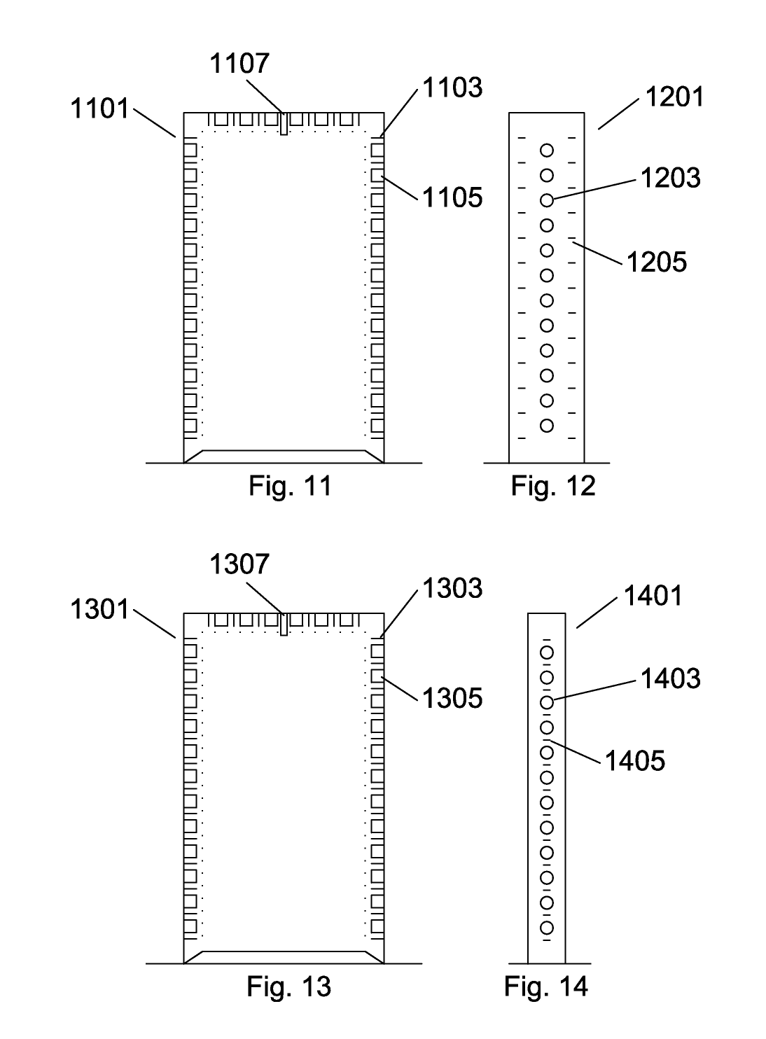

Further illustrated in FIG. 11 is a frontal view of a further example application of the present invention, in this case a static screening portal 1101 such as would be used at public venues such as airports or the like for the detection of person borne contraband or person borne improvised explosive devices. This portal 1101 will image a human standing still therewithin. Shown is the portal frame resting upon the ground, the interior of the portal frame having disposed a multiplicity of electrostatic exciters 1103 and electrostatic sensors 1105. Also shown is a video camera 1107. The purpose of said video camera is to ensure that the person being scanned exhibits no undue motion or displacement while the multiplicity of exciters and sensors perform electrostatic imaging.

Now shown in FIG. 12 is a side view 1201 of FIG. 11, clearly depicting the horizontal spacing between said electrostatic exciters 1205 and electrostatic sensors 1203.

Further illustrated in FIG. 13 is a frontal view of a further example application of the present invention, in this case a static screening portal 1301 such as would be used at public venues such as airports or the like. This portal will image a human moving therethrough. Shown is the portal frame resting upon the ground, the interior of the portal frame having disposed a multiplicity of electrostatic exciters 1303 and electrostatic sensors 1305. Also shown is a video camera 1307. The purpose of said video camera is to perform motion extraction as the human moves therethrough, so as to enable exciter 1303 and sensor 1305 synchronization thereto, in order that the multiplicity of exciters and sensors perform the electrostatic imaging of said human.

Now shown in FIG. 14 is a side view 1401 of FIG. 13, clearly depicting that said electrostatic exciters 1405 and electrostatic sensors 1403 are located within the same plane within said portal frame.

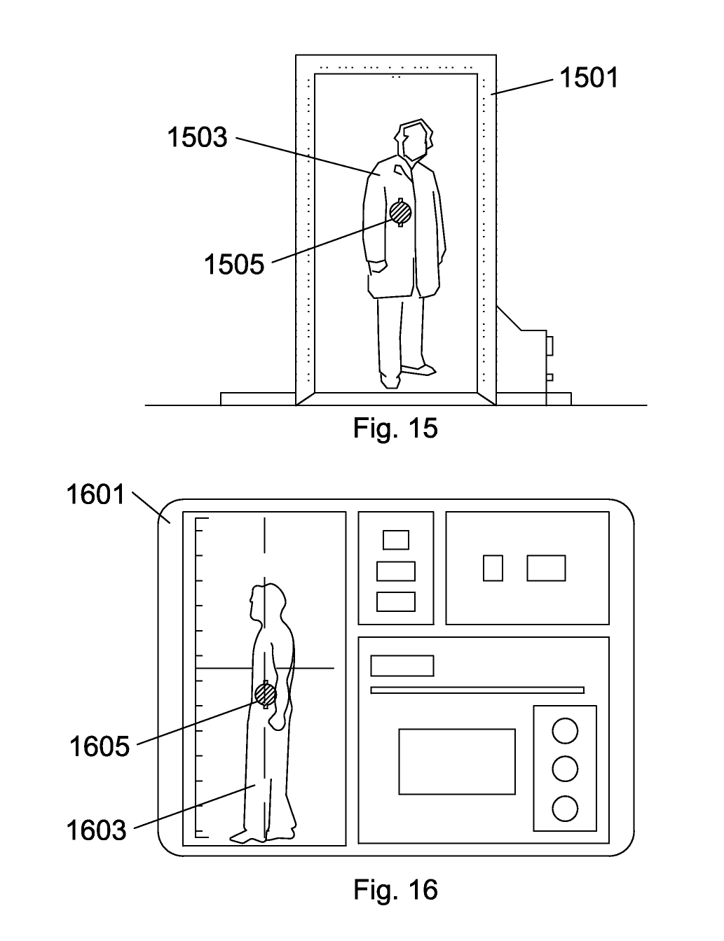

As shown in FIG. 15, there is illustrated a front view of said static screening portals 1501 described by way of FIGS. 11 and 13. Shown is the portal frame, resting upon the ground surface, along with control and sub processing electronics to the right thereof. A person 1503 is depicted within the portal, in this case carrying a suspected person borne, improvised explosive device 1505.

Now shown in FIG. 16, there is illustrated an example computer/video screen 1601 wherein a person 1603 is being dielectrically imaged by the static portals described by way of FIGS. 11, 12, 13, 14 and 15, and shown in silhouette/outline with a suspected target of interest 1605 indicated thereon. The target of interest could be a person borne improvised explosive device, a prostheses, or the like.

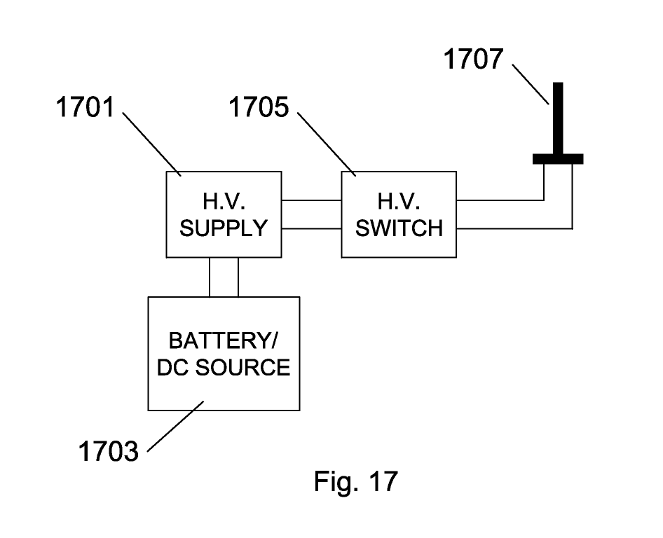

Turning now to FIG. 17, a schematic block diagram of an electrostatic exciter of the present invention is depicted. To create an electric field source by way of the electrostatic exciter(s) of the present invention, a high voltage supply 1701 is used. Such a high voltage supply may use, for example, a buck boost circuit or other such circuit to provide an output voltage on the order of 1,000 to 10,000 volts or more. The high voltage supply 1701 is powered by a source such as a D.C. supply or battery 1703. The output of the high voltage supply 1701 is switched using a high voltage switch 1705 that is in turn connected to an antenna 1707 for generation of an electric field gradient. The high voltage switch 1705 may be, for example, phototransistors, opto-couplers, cascaded field effect transistors, avalanche breakdown bipolar junction transistors, or the like. For example, a bank of approximately 40 4N35 phototransistors will suitably switch 5 kilovolts at 20-200 hz. Other high voltage switching techniques may also be used to generate the reference electric field gradient used with the present invention and the various embodiments described and envisioned herein.

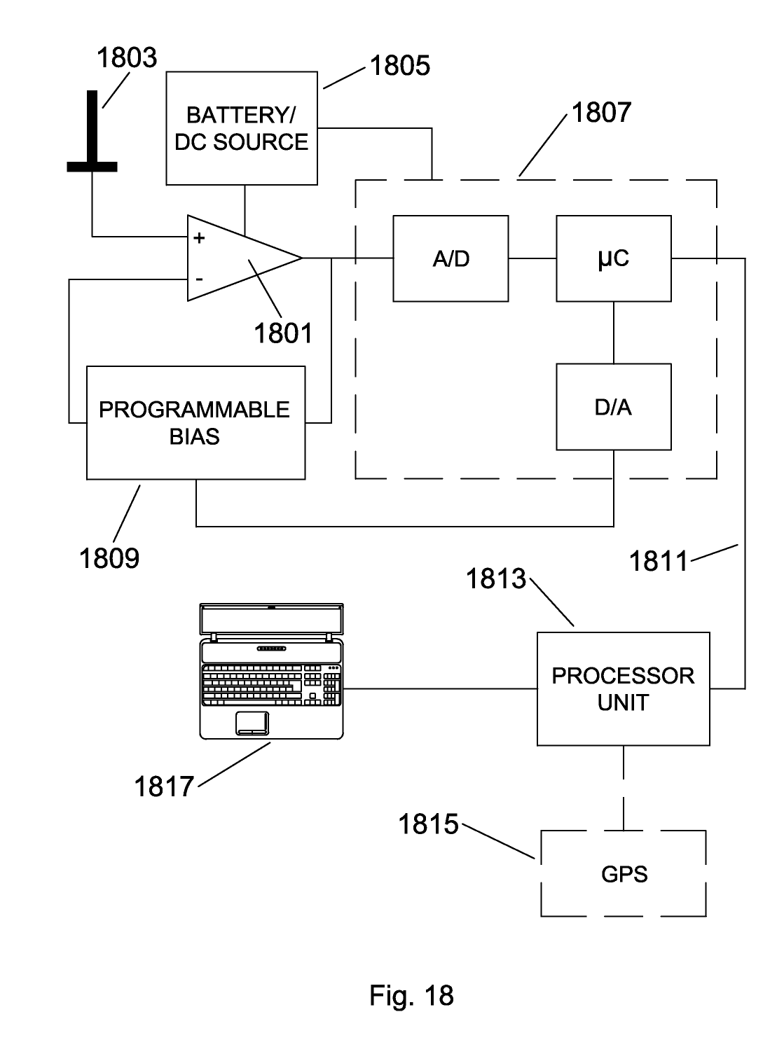

Lastly, turning to FIG. 18, a schematic block diagram of a sensor of the present invention is depicted. A high sensitivity operational amplifier (opamp), such as the LMC6081 or LMP7721 by National Semiconductor is depicted as 1801. The positive input of the opamp 1801 is connected to an antenna 1803 for sensing the electrostatic signature of interest. The opamp 1801 is powered by a battery or D.C. source 1805. The negative input for the opamp 1801 is provided with a feedback loop driven by a programmable bias 1809 where the bias for the feedback loop is determined by way of the output section 1807. The output of the opamp 1801 is received by an analog to digital converter and the resulting digital output is then fed to a microcontroller. The microcontroller then generates an output to a digital to analog converter where the analog output is then used to drive a programmable bias 1809 contained in the feedback loop of the opamp 1801. The microcontroller, analog to digital converter, and digital, to analog converter, are contained in the output section 1807. The output section 1807 further generates a digital output to a processor unit 1813. The connection between the output section 1807 and the processor unit 1813 may be a fiber optic cable, or a radiofrequency link, or the like. The digital output contains electric field strength data as captured by the analog output of the opamp 1801. This field strength data further contains temporal and spatial information that is used to provide a properly dimensioned electrostatic signature to be used by the processor unit 1813 for accurate detection and subsequent identification of an object being detected. The processor unit 1813 may further provide data including, for example, visual or display markers, to a computing device such as a laptop computer 1817 or the like. As the detection and identification of objects may involve a mobile system that makes frequent or recurring passes through a geographic location, a global positioning system 1815 may, in some embodiments of the present invention, be employed to track position. Further, a database or databases of electrostatic signatures may be used to increase accuracy. Databases may also be used to collect and store electrostatic signatures far later use. Later uses may include not only mapping of potential hazards, but also the creation and ongoing refinement of a knowledge base of electrostatic signatures of identified objects. The processor unit 1813 utilizes the electrostatic signature that is based partly on the permittivity of a target object. In addition, the sensor of FIG. 18 contains calibration routines that are necessary to adapt the sensing to various environmental conditions and sources. Calibration, or different electrostatic signature libraries, may be employed to deal with various operational platforms such as rubber tire vehicles, metal track vehicles, boats, and the like. In some embodiments of the present invention, multiple sensors are employed to provide directional capabilities.

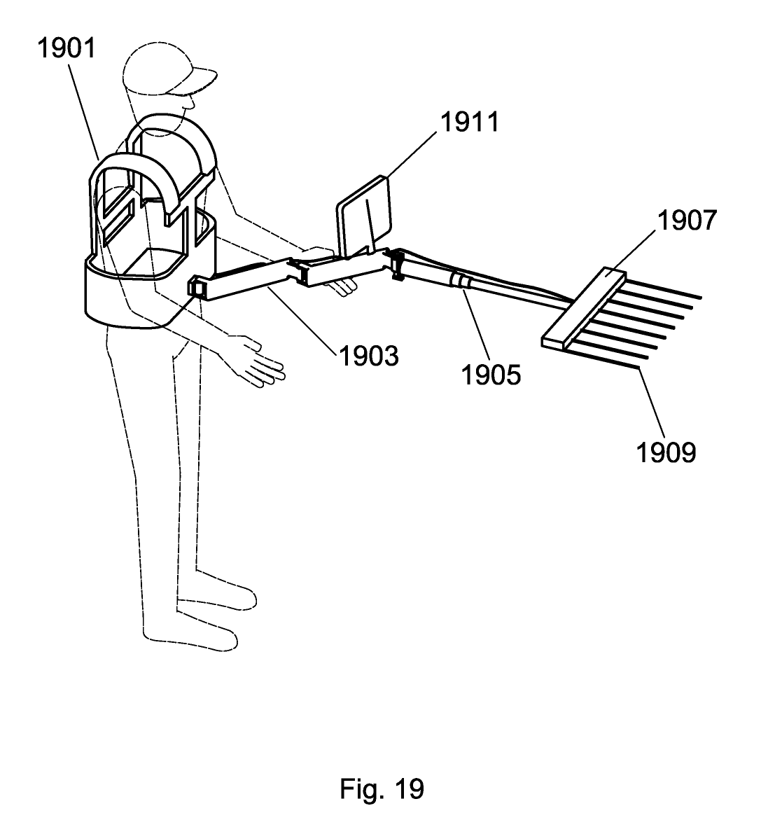

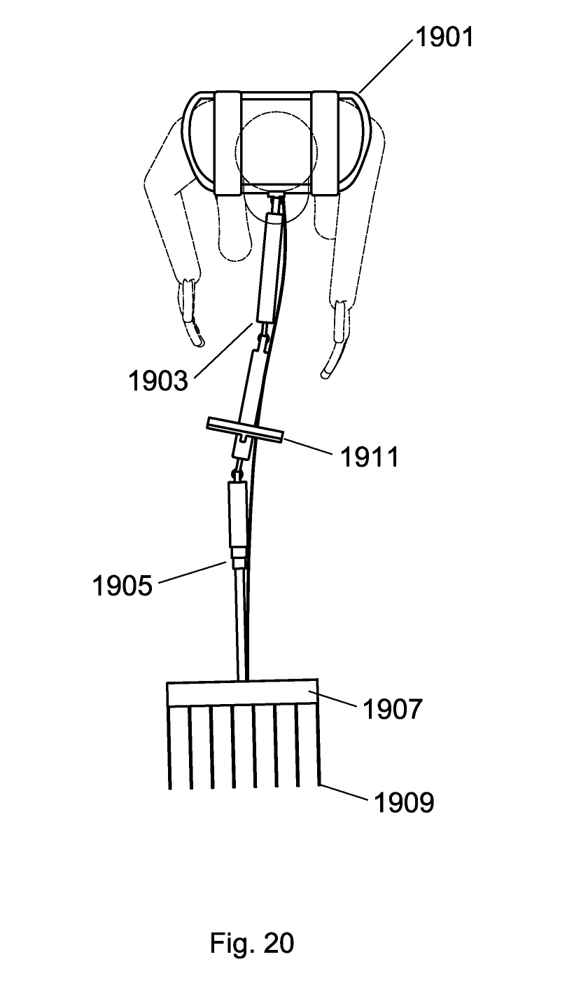

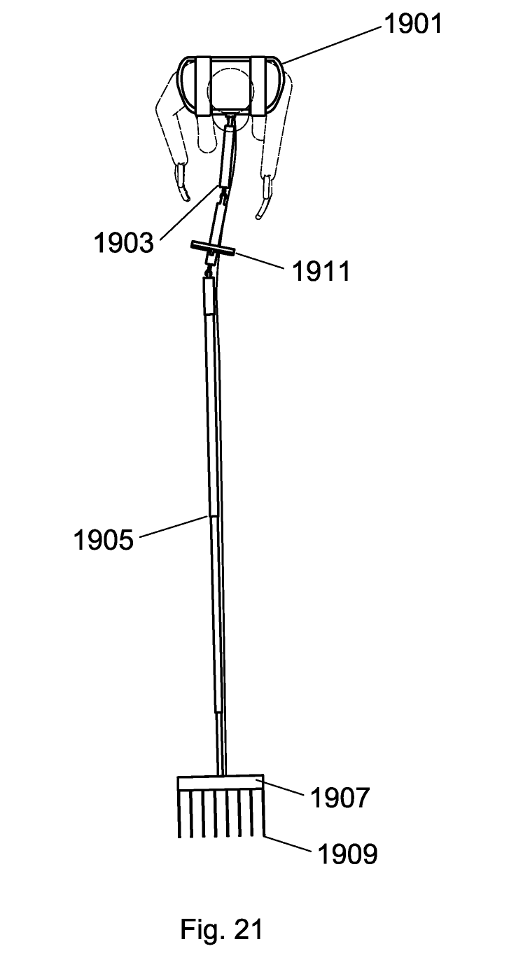

A further embodiment of the present invention can be seen in FIGS. 19-21. FIG. 19 shows a soldier-borne boom based electric field signature detector. An array of electric field signature detectors 1909 are attached to a fixture 1907. The fixture 1907 may be made from a suitable material such as a plastic, fiberglass reinforced plastic, or the like. An extendable boom 1905 is attached to the fixture 1907, and has a pivot mount 1903 that is then attached to a pack 1901 that is in turn worn by a soldier or other personnel. The extendable boom arrangement allows for electrostatic signature detection away from the immediate vicinity of the soldier operator. The pack and boom arrangement is designed in such a way that the torsional forces of the extended boom and related equipment do not create undue fatigue on the soldier operator. The electrostatic signature detector array operates similar to that heretofore described. An electronic display such as an LED monitor 1911 can be seen mounted to the boom and adjusted to provide proper viewing angle by the soldier operator. FIG. 20 shows a plan view of the soldier-borne boom based electric field signature detector with the boom in a partially retracted position, and FIG. 21 shows a plan view of the soldier-borne boom based electric field signature detector with the boom in an extended position.

It is, therefore, apparent that there has been provided, in accordance with the various objects of the present invention. Electric Field Signature Detection Using Exciter-Sensor Arrays. While the various objects of this invention have been described in conjunction with preferred embodiments thereof, it is evident that many alternatives, modifications, and variations will be apparent to those skilled in the art. Accordingly, it is intended to embrace all such alternatives, modifications and variations that fall within the spirit and broad scope of the present invention as defined by this specification and the attached drawings.

What is claimed is:

1. An electric field signature detector for detecting and identifying objects comprising:
a high voltage exciter electrically coupled to an antenna for providing an electrostatic field; and
a sensor for detecting an electrostatic signature resulting from interaction of an object being detected with the electrostatic field generated by the high voltage exciter;
the sensor comprising a high sensitivity operational amplifier, an antenna electrically coupled to a positive input of the high sensitivity operational amplifier, a programmable bias electrically coupled to a negative input feedback loop of the high sensitivity operational amplifier and an output section electrically coupled to an output of the high sensitivity operational amplifier.

2. The electric field signature detector of claim 1, wherein the output section of the sensor comprises. a microcontroller, an analog to digital converter and a digital to analog converter.

3. The electric field signature detector of claim 1, further comprising a processor unit electrically coupled to the output section of the sensor.

4. The electric field signature detector of claim 3, further comprising a computing device electrically coupled to the processor unit.

5. The electric field signature detector of claim 3, further comprising a global positioning system electrically coupled to the processor unit.

6. The electric field signature detector of claim 1, further comprising a database of electrostatic signatures stored on a data storage device.

7. The electric field ,signature detector of claim 1, further comprising a database of calibration routines stored on a data storage device.

8. An array of electric field signature detectors comprising:
high voltage exciters electrically coupled to a plurality of antennae for providing an electrostatic field matrix:
sensors for detecting an electrostatic signature resulting from interaction of an object being detected with the electrostatic field matrix generated by the plurality of high voltage exciters:
each sensor comprising a high sensitivity operational amplifier, an antenna electrically coupled to a positive input of the high sensitivity operational amplifier, a programmable bias electrically coupled to a negative input feedback loop of the high sensitivity operational amplifier and an output section electrically coupled to an output of the high sensitivity operational amplifier; and
a platform that contains the high voltage exciters and the sensors.

9. The array of electric field signature detectors of claim 8 wherein the platform is a sensor node and an exciter node.

10. The array of electric field signature detectors of claim 8 wherein the platform is a plurality of sensor nodes and a plurality of exciter nodes.

11. The array of electric field signature detectors of claim 8 wherein the platform comprises two sensor nodes and a single exciter node.

12. The array of electric field signature detectors of claim 8 wherein the platform is a vehicular based platform.

13. The array of electric field signature detectors of claim 8 wherein the platform is a soldier based platform.

14. The array of electric field signature detectors of claim 8 wherein the platform is a static screening portal.

15. The array of electric field signature detectors of claim 8 wherein for every sensor there are a plurality of exciters.

16. The array of electric field signature detectors of claim 8 wherein for every exciter there are a plurality of sensors.

17. The array of electric field signature detectors of claim 8 wherein there are an equal number of exciters and sensors.

18. A system for detecting and identifying objects by way of electrostatic signatures, the system comprising:
a plurality of electrostatic excitation nodes;
an electrostatic drive system electrically coupled to the plurality of electrostatic excitation nodes;
a controller;
a plurality of electrostatic sensing nodes;
an electrostatic sensing acquisition system electrically coupled to the plurality of electrostatic sensing nodes; and
a processing and display system.

19. The system for detecting and identifying objects by way of electrostatic signatures of claim 18 wherein the processing and display system is a computer.

20. The system for detecting and identifying objects by way of electrostatic signatures of claim 18 wherein the processing and display system is wirelessly coupled to the controller.
